(19) United States
(12) Patent Application Publication
(10) Pub. No.: US 2025/0227922 A1
(43) Pub. Date: Jul. 10, 2025

(54) SEMICONDUCTOR DEVICE AND FORMATION METHOD THEREOF

(71) Applicant: Winbond Electronics Corp., Taichung City (TW)

(72) Inventors: Keng-Ping LIN, Taichung City (TW); Tzu-Ming OU YANG, Taichung City (TW); Shu-Ming LI, Kaohsiung City (TW)

(21) Appl. No.: 18/654,410

(22) Filed: May 3, 2024

(30) Foreign Application Priority Data
Jan. 10, 2024 (TW) 113101038

(51) Int. Cl. H10B 12/00

(52) U.S. Cl. CPC H10B 12/50; H10B 12/09; H10B 12/315; H10B 12/34

(57) ABSTRACT

A semiconductor device and a formation method thereof are provided. The semiconductor device includes a substrate, an isolation structure, a word line structure, first and second dielectric pillars, and first and second conductive layers. The substrate has an active area and a dummy area. The isolation structure is disposed in the dummy area. The word line structure is disposed in the active area. The first dielectric pillar is disposed on the isolation structure and the word line structure. The second dielectric pillar is disposed on the isolation structure. The first conductive layer is disposed in the active area. The second conductive layer is disposed on the first conductive layer and the second dielectric pillar. The bottom surface of the second conductive layer in the dummy area is lower than the top surface of the first dielectric pillar in the dummy area.

### CROSS REFERENCE TO RELATED APPLICATIONS

This Application claims priority of Taiwan Patent Application No. 113101038, filed on Jan. 10, 2024, the entirety of which is incorporated by reference herein.

### TECHNICAL FIELD

Some embodiments of the present disclosure relate to a semiconductor device and a formation method thereof, and, in particular, to a semiconductor device that may be used as a memory device and a formation method thereof.

### BACKGROUND

The shrinking size of semiconductors may increase device density and improve performance. However, unnecessary conduction, leakage current, short-circuiting, and/or reduced reliability may occur between adjacent elements.

### SUMMARY

In view of the above problems, the present disclosure avoids the problem of leakage current by forming a second dielectric pillar on the isolation structure. For example, by forming a second dielectric pillar on the isolation structure and in the dummy area, the second conductive layer disposed on the second dielectric pillar is prevented from generating leakage current in the dummy area. Therefore, the present disclosure may avoid leakage current between adjacent elements and/or improve the reliability of the semiconductor device.

In some embodiments, a semiconductor device includes a substrate, an isolation structure, a word line structure, a first dielectric pillar, a second dielectric pillar, a first conductive layer, and a second conductive layer. The substrate has an active area and a dummy area adjacent to the active area. The isolation structure is disposed in the dummy area and disposed in the substrate. The word line structure is disposed in the active area and disposed in the substrate. The first dielectric pillar is disposed on the isolation structure and the word line structure. The second dielectric pillar is disposed on the isolation structure. The first conductive layer is disposed in the active area and disposed on the substrate. The second conductive layer is disposed on the first conductive layer and the second dielectric pillar. The bottom surface of the second conductive layer in the dummy area is lower than the top surface of the first dielectric pillar in the dummy area.

In some embodiments, a method of forming a semiconductor device includes providing a substrate having an active area and a dummy area adjacent to the active area. An isolation structure is formed in the dummy area and in the substrate. A word line structure is formed in the active area and in the substrate. A first dielectric pillar is formed on the isolation structure and the word line structure. A second dielectric pillar is formed on the isolation structure. The top surface of the second dielectric pillar is lower than the top surface of the first dielectric pillar. The first conductive layer is formed in the active area and on the substrate. The second conductive layer is formed on the first conductive layer and the second dielectric pillar.

### BRIEF DESCRIPTION OF THE DRAWINGS

FIGS. 1 to 11 are schematic cross-sectional views illustrating formation of a semiconductor device at various stages according to some embodiments of the present disclosure, respectively.

FIG. 12 is a schematic cross-sectional view of a semiconductor device according to some embodiments of the present disclosure.

### DETAILED DESCRIPTION

In the present disclosure, the respective directions are not limited to three axes of the rectangular coordinate system, such as the X-axis, the Y-axis, and the Z-axis, and may be interpreted in a broader sense. For example, the X-axis, the Y-axis, and the Z-axis may be perpendicular to each other, but the present disclosure is not limited thereto. For convenience of description, hereinafter, the X-axis direction is the first direction D1 (width direction) and the Z-axis direction is the second direction D2 (height or depth direction). In some embodiments, the second direction D2 may be a normal direction of the substrate. In some embodiments, the schematic cross-sectional views described herein are schematic views of the XZ plane.

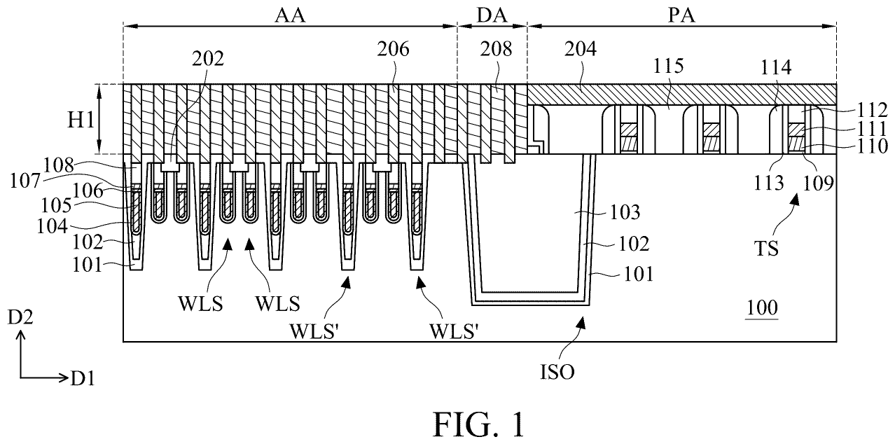

Referring to FIG. 1, which is a schematic cross-sectional view of forming a semiconductor device at various stages according to some embodiments of the present disclosure. The schematic cross-sectional view described herein is a schematic cross-sectional view taken along a direction that is parallel to the extension direction of the bit lines, but without overlapping the bit lines. In some embodiments, a substrate 100 may be provided. The substrate 100 may include a silicon wafer, a bulk semiconductor, or a semiconductor-on-insulation substrate. Other types of substrate 100 are, for example, multi-layer substrates or gradient substrates.

The substrate 100 may have an active area AA, a dummy area DA, and a peripheral area PA. The active area AA may be adjacent to the dummy area DA, and the dummy area DA may be between the active area AA and the peripheral area PA. The memory cell of the semiconductor device may be disposed in a storage area. The storage area may include the active area AA and the dummy area DA, and the storage area may be adjacent to the peripheral area PA. The memory cell located in the active area AA may perform the storage function, and the memory cell located in the dummy area DA does not perform the storage function. In addition, peripheral circuits for controlling the memory cell may be disposed in the peripheral area PA.

A plurality of trenches (not shown) may be formed in the substrate 100, and an isolation material may be formed in the trenches, so as to form an isolation structure ISO in the dummy area DA and provide electrical isolation. The isolation structure ISO may be a single-layer or multi-layer structure. For example, the multi-layered isolation structure ISO may include a first dielectric layer 101, a second dielectric layer 102, and/or a dielectric filler 103 and they may be made of oxide, nitride, oxynitride, or the like. For example, the first dielectric layer 101 may include silicon oxide, the second dielectric layer 102 may include silicon nitride, and the dielectric filler 103 may include spin-on glass (SOG) oxide.

A word line structure WLS may be formed in the active area AA. The top surface of the word line structure WLS may be lower than the top surface of the substrate 100, so the word line structure WLS may be a buried word line structure. A set of word lines may include a pair of word line structures WLS and passing word line structures WLS′ disposed on both sides of the pair of word line structures WLS. The word line structure WLS and the passing word line structure WLS′ may include the first dielectric layer 101, the second dielectric layer 102, a first liner 104, a first word line conductive layer 105, a second liner 106, a second word line conductive layer 107, and the third dielectric layer 108.

In some embodiments, the first liner 104, the first word line conductive layer 105, the second liner 106, and/or the second word line conductive layer 107 may include polycrystalline silicon (polysilicon); amorphous silicon; metals such as tungsten, copper, silver, gold, and cobalt; metal nitrides such as tungsten nitride and titanium nitride; conductive metal oxides; other suitable materials; the like; or a combination thereof, but the present disclosure is not limited thereto. The material of the third dielectric layer 108 may be the same as or different from the material of the first dielectric layer 101. For example, the first liner 104 may include titanium nitride, the first word line conductive layer 105 may include polysilicon, the second liner 106 may include titanium nitride, the second word line conductive layer 107 may include tungsten, and the third dielectric layer 108 may include silicon oxide.

Furthermore, a contact 202 may be formed on the word line structure WLS, and the contact 202 is electrically connected to the subsequently formed first conductive layer. The contact 202 may be disposed between a pair of word line structures WLS and may be disposed on an upper portion of the word line structure WLS. The contact 202 may be used as a gate contact (GC) of the memory cell of the semiconductor device, so the contact 202 may be used to electrically connect with a gate electrode of the transistor structure in the peripheral area PA of the semiconductor device.

In some embodiments, a transistor structure TS may be formed in the peripheral area PA and on the substrate 100. The transistor structure TS may include a fourth dielectric layer 109, a first transistor conductive layer 110, a second transistor conductive layer 111, a fifth dielectric layer 112, a first spacer 113, and a second spacer 114.

In some embodiments, the material of the fourth dielectric layer 109, the fifth dielectric layer 112, the first spacer 113, and/or the second spacer 114 may be the same as or different from the material of the first dielectric layer 101. The material of the first transistor conductive layer 110 and/or the second transistor conductive layer 111 may be the same as or different from the material of the first word line conductive layer 105. For example, the fourth dielectric layer 109 may include silicon oxide, the first transistor conductive layer 110 may include polysilicon, the second transistor conductive layer 111 may include tungsten, the fifth dielectric layer 112 may include silicon nitride, the first spacer 113 may include silicon nitride, and the second spacer 114 may include silicon oxide.

In some embodiments, a planarization layer 115 is formed on the transistor structure TS to cover the side surface of the transistor structure TS. In some embodiments, the capping layer 204 is formed on the planarization layer 115 to cover the top surface of the transistor structure TS and the top surface of the planarization layer 115. The material of the planarization layer 115 and/or the capping layer 204 may be the same as or different from the material of the first dielectric layer 101. For example, the planarization layer 115 may include SOG oxide, and the capping layer 204 may include silicon nitride.

In some embodiments, the first dielectric pillars 206 and the second dielectric pillars 208 may be respectively formed in the active area AA and the dummy area DA and may be formed on the word line structure WLS, the passing word line structure WLS′, and the isolation structure ISO. The second dielectric pillars 208 and the first dielectric pillars 206 may be alternately disposed in the first direction D1. The materials of the first dielectric pillar 206 and the second dielectric pillar 208 may be the same as or different from the material of the first dielectric layer 101. For example, the first dielectric pillar 206 may include a nitride, such as silicon nitride, and the second dielectric pillar 208 may include an oxide, such as SOC oxide. In some embodiments, the second dielectric pillar 208 may have a first height H1 in the second direction D2. The first height H1 may be greater than or equal to 0 and less than or equal to 250 nm. For example, the first height H1 may be 50 nm, 100 nm, 150 nm, 200 nm, 250 nm, or any value or any range of values between the aforementioned values, but the present disclosure is not limited thereto.

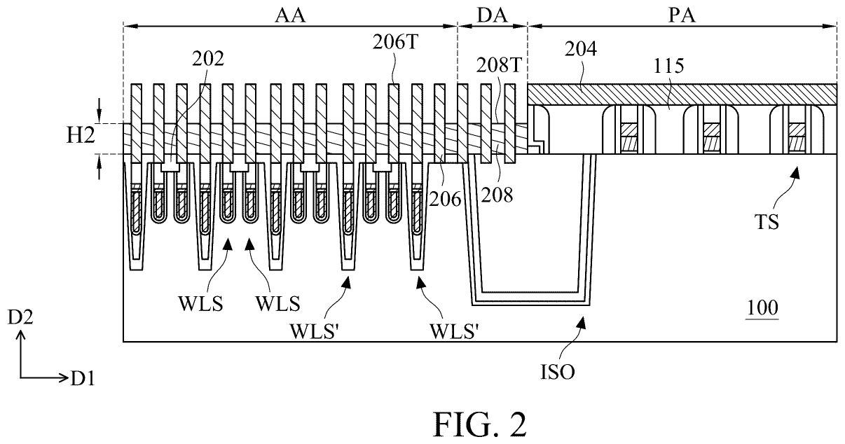

Referring to FIG. 2, in some embodiments, the second dielectric pillar 208 is etched back so that the top surface 208T of the second dielectric pillar 208 is lower than the top surface 206T of the first dielectric pillar 206. The etch back process may be a partial wet etching process. In the second direction D2, the etched-back second dielectric pillar 208 has a second height H2, and the second height H2 is 20% to 75% of the first height H1. For example, the ratio of the second height H2 to the first height H1 (H2/H1) may be 0.2, 0.3, 0.4, 0.5, 0.6, 0.7, 0.75, or any value or any range of values between the aforementioned values, but the present disclosure is not limited thereto.

In some embodiments, the depth of the etch-back process may be 25% to 80% of the first height H1. For example, the depth of the etch-back process may be 25%, 30%, 40%, 50%, 60%, 70%, 80%, or any value or any range of values between the aforementioned values of the first height H1, but the present disclosure is not limited thereto. In some embodiments, the depth of the etch-back process may be 20 nm-80 nm. For example, the depth of the etch-back process may be 20 nm, 30 nm, 40 nm, 50 nm, 60 nm, 70 nm, 80 nm, or any value or any range of values between the aforementioned values, but the present disclosure is not limited thereto. The etch-back process is performed to form a recess (not shown) on the second dielectric pillar 208. Since the depth of the performed etch-back process is substantially the same as the thickness of the first photoresist layer subsequently formed in the recess, the thickness of the first photoresist layer in the recess may be adjusted by controlling the depth of the etch-back process. For example, when the depth of the etch-back process may be 20 nm, the thickness of the first photoresist layer in the recess may be 20 nm. Therefore, over-etching during the subsequent wet etching processes may be blocked by the first photoresist layer in the recess. Next, the second dielectric pillar 208 may be patterned to adjust the position of the second dielectric pillar 208.

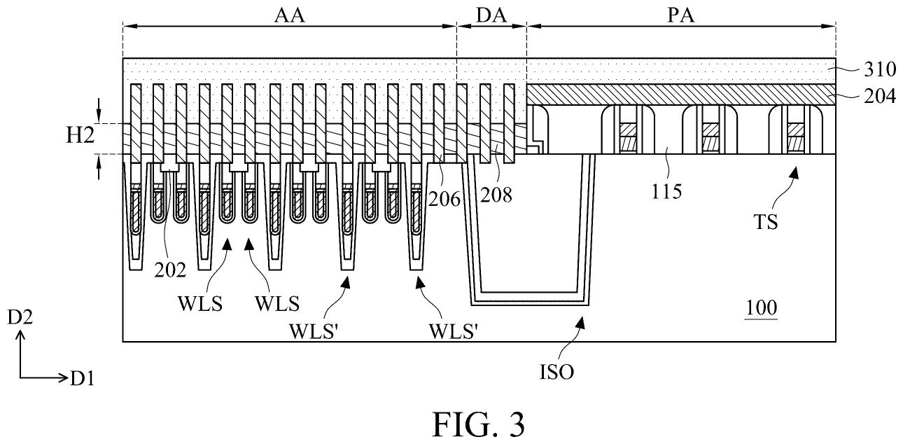

Referring to FIGS. 3 to 7, the patterning of the second dielectric pillar 208 may include forming a photoresist layer to cover the second dielectric pillar 208 in the dummy area DA. Next, the second dielectric pillar 208 in the active area AA is removed by performing a wet etching process using the photoresist layer as an etching mask. Then, the photoresist layer is removed. The photoresist layer may include two photoresist layers with different viscosities.

Specifically, as shown in FIG. 3, the first photoresist layer 310 is formed on the active area AA, the dummy area DA, and the peripheral area PA, and is formed on the first dielectric pillar 206 and the second dielectric pillar 208. The first photoresist layer 310 may include oxide, nitride, oxynitride, or carbon-based materials. For example, the first photoresist layer 310 may include spin-on carbon (SOC) or a carbon-based material with a lower viscosity than SOC so as to completely fill the recess (not shown) on the second dielectric pillar 208. Accordingly, by using a carbon-based material with low viscosity, the reliability of filling the recess with the first photoresist layer 310 may be improved.

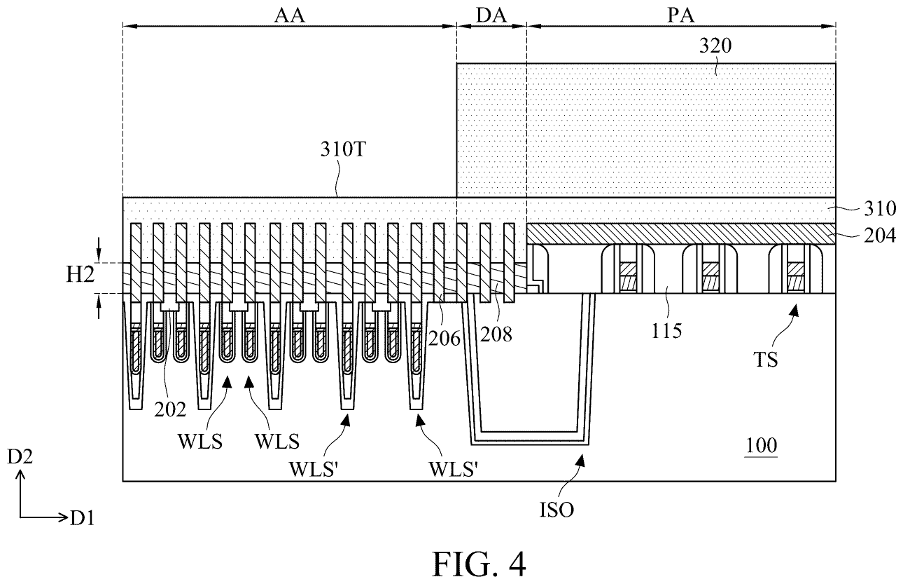

As shown in FIG. 4, a second photoresist layer 320 is formed on the first photoresist layer 310, and the second photoresist layer 320 exposes the top surface 310T of the first photoresist layer 310 in the active area AA. In some embodiments, the viscosity of the first photoresist layer 310 is lower than the viscosity of the second photoresist layer 320 so that the first photoresist layer 310 may more easily completely fill the recess (not shown), and the second photoresist layer 320 with greater viscosity may better form a mask. In some embodiments, the material and formation method of the second photoresist layer 320 may be the same as or different from that of the first photoresist layer 310.

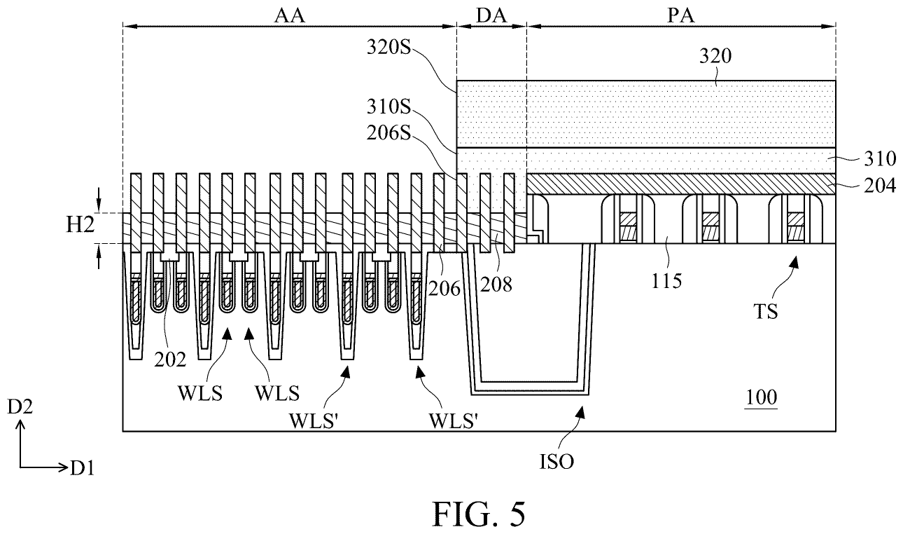

As shown in FIG. 5, by using the first photoresist layer 310 as an etching mask to perform an etching process, the first photoresist layer 310 in the active area AA is removed. Thus, the side surface 310S of the first photoresist layer 310 is aligned with the side surface 320S of the second photoresist layer 320. The side surface 310S of the first photoresist layer 310 and the side surface 320S of the second photoresist layer 320 may be aligned with the side surface 206S of the first dielectric pillar 206 located in the dummy area DA and closest to the active area AA.

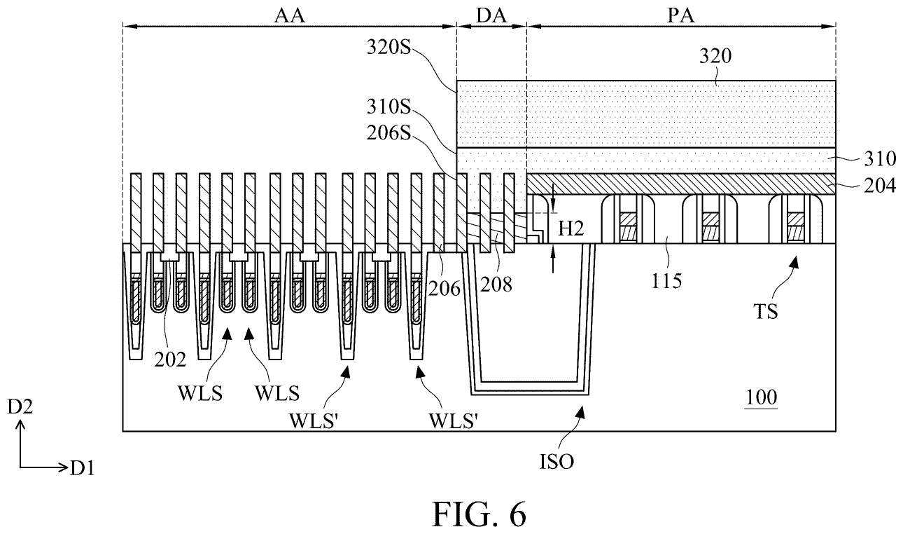

As shown in FIG. 6, the second dielectric pillar 208 in the active area AA is removed by performing a wet etching process using the first photoresist layer 310 and the second photoresist layer 320 together as an etching mask. Since the first photoresist layer 310 is disposed under the second photoresist layer 320 in the dummy area DA, over-etching during the wet etching process caused by edge warping or seams of the second photoresist layer 320 with greater viscosity may be avoided. For example, in the case where the second photoresist layer 320 is directly formed on the second dielectric pillar 208, the etchant used in the wet etching process may penetrate from the bottom portion of the second photoresist layer 320 or from the boundary of the second photoresist layer 320 and other elements. Therefore, forming the first photoresist layer 310 with low viscosity, and then forming the second photoresist layer 320 with high viscosity may effectively prevent the etchant from over-etching in the dummy area DA. Therefore, the leakage current between adjacent elements is avoided and/or the reliability of the semiconductor device is improved.

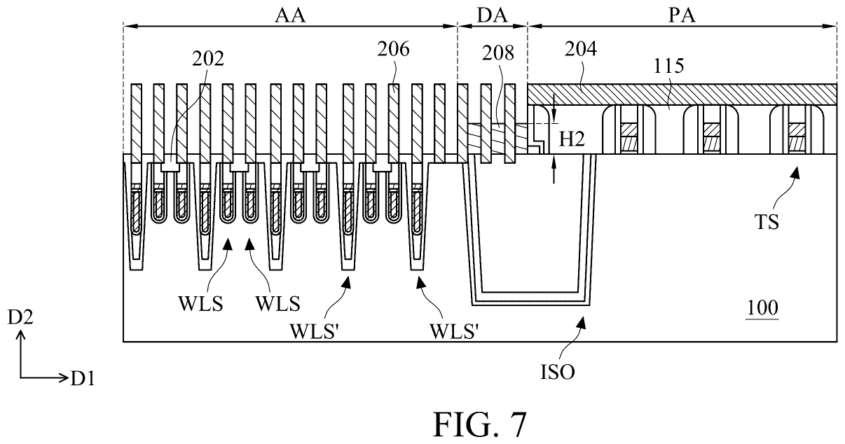

As shown in FIG. 7, the photoresist layer may be further removed by a removal process such as an ashing process.

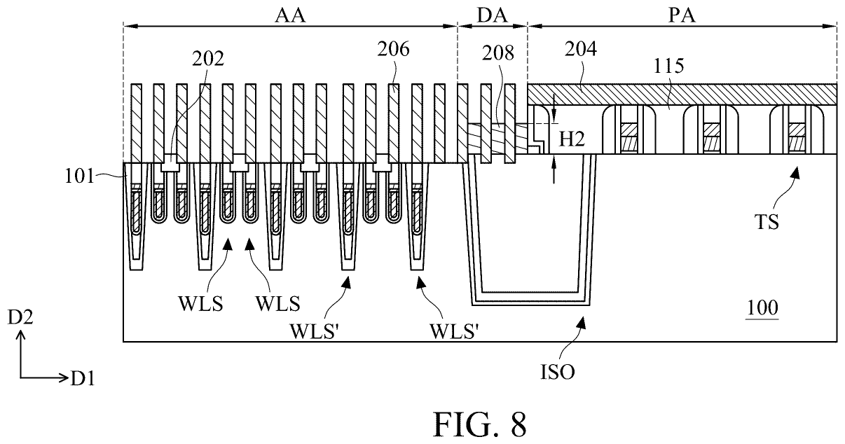

Referring to FIG. 8, a portion of the word line structure WLS and a portion of the passing word line structure WLS′ are removed, so as to expose the top surface of the substrate 100. For example, portions of the first dielectric layer 101 of the word line structure WLS and the passing word line structure WLS′ may be removed.

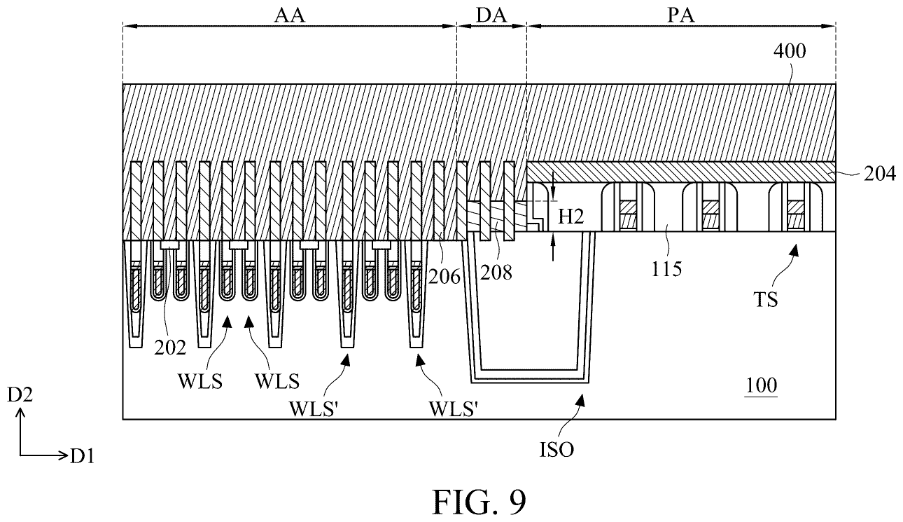

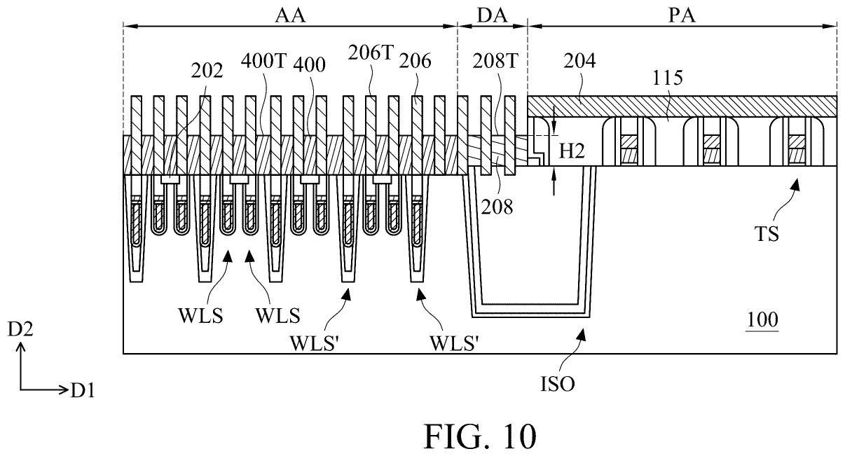

Referring to FIGS. 9 and 10, a first conductive layer 400 is formed in the active area AA and on the exposed top surface of the substrate 100 so that the first conductive layer 400 may be electrically connected to the contact 202.

Specifically, the material of the first conductive layer 400 is deposited on the substrate 100, the first dielectric pillar 206, and the second dielectric pillar 208. The material and formation method of the first conductive layer 400 may be the same as or different from that of the first word line conductive layer 105.

As shown in FIG. 10, the material of the first conductive layer 400 is etched back so that the top surface 400T of the first conductive layer 400 is lower than the top surface 206T of the first dielectric pillar 206. For example, in the second direction D2, the height of the first conductive layer 400 may be between 50 nm and 150 nm. The top surface 400T of the first conductive layer 400 in the active area AA may be substantially aligned with the top surface 208T of the second dielectric pillar 208 in the dummy area DA. The first conductive layer 400 in the dummy area DA may be substantially completely removed.

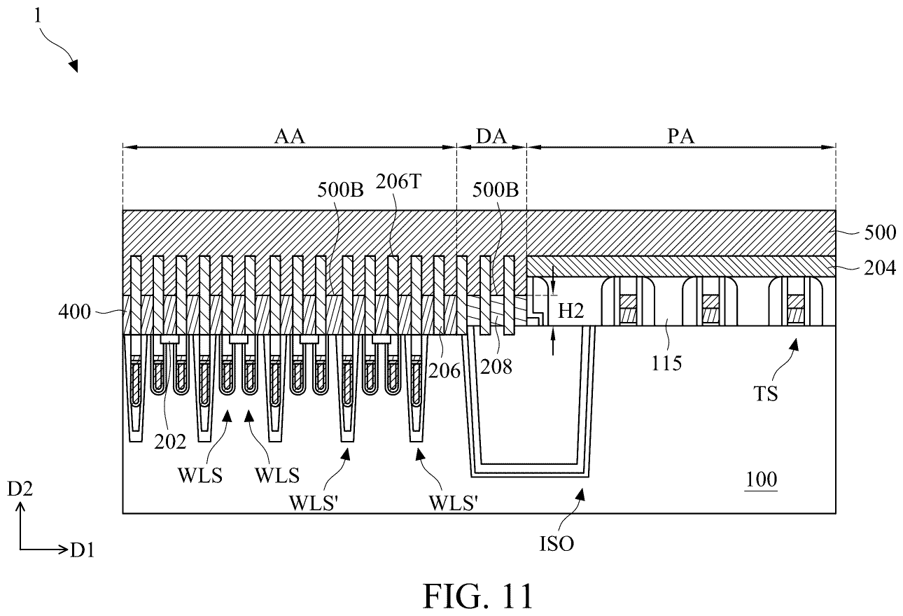

Referring to FIG. 11, a second conductive layer 500 is formed on the first conductive layer 400, the first dielectric pillar 206, the second dielectric pillar 208, and the capping layer 204, in order to obtain a semiconductor device 1. The bottom surface 500B of the second conductive layer 500 in the dummy area DA may be lower than the top surface 206T of the first dielectric pillar 206 in the dummy area DA. The bottom surface 500B of the second conductive layer 500 in the dummy area DA may be substantially aligned with the bottom surface 500B of the second conductive layer 500 in the active area AA. At the boundary of the active area AA and the dummy area DA, the first dielectric pillar 206 may be disposed between the first conductive layer 400 and the second dielectric pillar 208. In the dummy area DA, the second conductive layer 500 is in direct contact with the second dielectric pillar 208. Accordingly, since the second dielectric pillar 208 is disposed below the second conductive layer 500, the unnecessary conduction, the leakage current and/or the short circuit between the second conductive layer 500 and the elements below the second conductive layer 500 may be avoided.

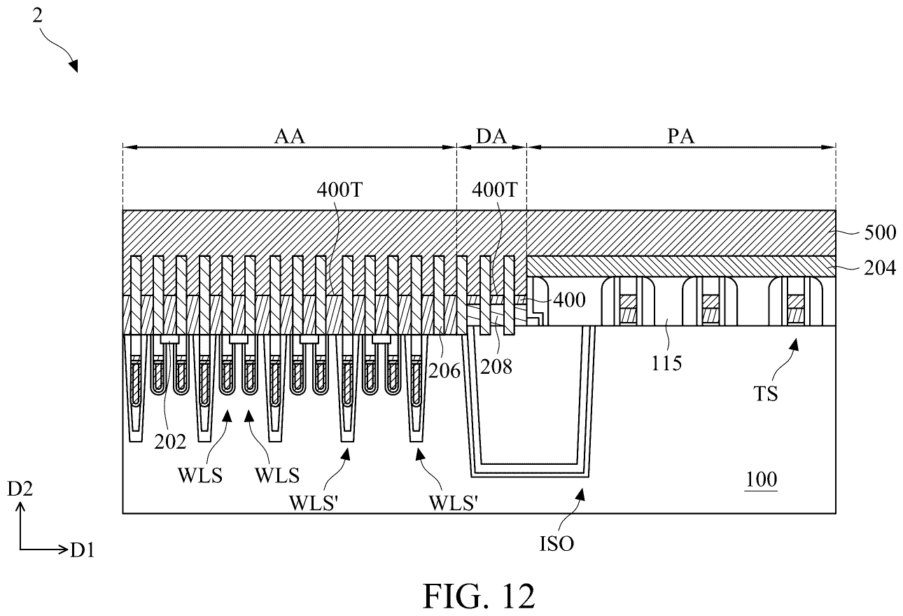

Referring to FIG. 12, which is a schematic cross-sectional view of a semiconductor device 2 according to some embodiments of the present disclosure. In some embodiments, similar to FIG. 10, after the etch-back process, the first conductive layer 400 in the dummy area DA is remained. Therefore, the top surface 400T of the first conductive layer 400 in the active area AA may be substantially aligned with the top surface 400T of the first conductive layer 400 in the dummy area DA. The top surface 400T of the first conductive layer 400 in the active area AA may be higher than the top surface 208T of the second dielectric pillar 208 in the dummy area DA. Next, similar to FIG. 11, the second conductive layer 500 may be formed on the first conductive layer 400 and the second dielectric pillar 208 in order to obtain a semiconductor device 2 (as shown in FIG. 12). In the dummy area DA, the first conductive layer 400 may be between the second conductive layer 500 and the second dielectric pillar 208. In the dummy area DA, the first conductive layer 400 may be in directly contact with the second conductive layer 500, and the first conductive layer 400 may be in directly contact with the second dielectric pillar 208. Accordingly, even if the first conductive layer 400 and the second conductive layer 500 are in direct contact, since the second dielectric pillar 208 is disposed under the second conductive layer 500 and the first conductive layer 400, the unnecessary conduction, the leakage current and/or the short circuit between the first conductive layer 400 and the elements below the first conductive layer 400 may be avoided.

In some embodiments, further processes may be performed on semiconductor device 1 and/or 2, in order to form memory devices. For example, landing pads may be formed on the semiconductor device 1 and/or 2, and storage contacts (SC) (also referred as capacitor contacts) may be formed on the landing pads.

In summary, the semiconductor device of the present disclosure includes the second dielectric pillar located on the isolation structure, thereby avoiding the unnecessary conduction, the leakage current and/or the short circuit between adjacent elements, and/or improving the reliability of the semiconductor device. Furthermore, the formation method of the semiconductor device of the present disclosure includes the formation of the second dielectric pillar in the dummy area by making the top surface of the second dielectric pillar lower than the top surface of the first dielectric pillar and patterning the second dielectric pillar. Therefore, the process complexity and cost may be reduced (for example, when the second dielectric pillar does not be disposed in the dummy area, photoresists of different sizes need to be repeatedly formed to determine the damage range caused by performing the wet etching process), the leakage current generated between adjacent elements may be avoided, and/or the reliability of the semiconductor device may be improved. In addition, the formation method of the semiconductor device of the present disclosure may include using photoresist layers with different viscosities to avoid over-etching during the etching process.

The foregoing outlines features of several embodiments of the present disclosure, so that a person of ordinary skill in the art may better understand the aspects of the present disclosure. A person of ordinary skill in the art should appreciate that the present disclosure may be readily used as a basis for designing or modifying other processes and structures for carrying out the same purposes and/or achieving the same advantages of the embodiments introduced herein. A person of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate having an active area and a dummy area adjacent to the active area;
an isolation structure disposed in the dummy area and disposed in the substrate;
a word line structure disposed in the active area and disposed in the substrate;
a first dielectric pillar disposed on the isolation structure and the word line structure;
a second dielectric pillar disposed on the isolation structure;
a first conductive layer disposed in the active area and disposed on the substrate; and
a second conductive layer disposed on the first conductive layer and the second dielectric pillar,
wherein a bottom surface of the second conductive layer in the dummy area is lower than a top surface of the first dielectric pillar in the dummy area.

2. The semiconductor device according to claim 1, wherein the first dielectric pillar is between the first conductive layer and the second dielectric pillar.

3. The semiconductor device according to claim 1, wherein in the dummy area, the second conductive layer is in contact with the second dielectric pillar.

4. The semiconductor device according to claim 1, wherein in the dummy area, the first conductive layer is between the second conductive layer and the second dielectric pillar.

5. The semiconductor device according to claim 1, wherein in the dummy area, the first conductive layer is in contact with the second conductive layer, and the first conductive layer is in contact with the second dielectric pillar.

6. The semiconductor device according to claim 1, wherein the bottom surface of the second conductive layer in the dummy area is aligned with the bottom surface of the second conductive layer in the active area.

7. The semiconductor device according to claim 1, further comprising:
a contact disposed on the word line structure and being electrically connected to the first conductive layer.

8. The semiconductor device according to claim 1, wherein the substrate further comprises a peripheral area, and the dummy area is between the active area and the peripheral area, and the semiconductor device further comprises:
a transistor structure disposed in the peripheral area and disposed on the substrate;
a planarization layer disposed on the transistor structure; and
a capping layer disposed on the planarization layer.

9. The semiconductor device according to claim 1, wherein the first dielectric pillar comprises a nitride, and the second dielectric pillar comprises an oxide.

10. A method of forming a semiconductor device, comprising:
provide a substrate having an active area and a dummy area adjacent to the active area;
forming an isolation structure in the dummy area and in the substrate;
forming a word line structure in the active area and in the substrate;
forming a first dielectric pillar on the isolation structure and the word line structure;
forming a second dielectric pillar on the isolation structure, wherein a top surface of the second dielectric pillar is lower than a top surface of the first dielectric pillar;
forming a first conductive layer in the active area and on the substrate; and
forming a second conductive layer on the first conductive layer and the second dielectric pillar.

11. The method according to claim 10, wherein the formation of the second dielectric pillar on the isolation structure further comprises:
forming the second dielectric pillar in the active area and the dummy area, wherein the second dielectric pillar is disposed on the isolation structure and the word line structure;
etching back the second dielectric pillar so that the top surface of the second dielectric pillar is lower than the top surface of the first dielectric pillar; and
patterning the second dielectric pillar.

12. The method according to claim 11, wherein:
the second dielectric pillar is formed in the active area and the dummy area, wherein the second dielectric pillar has a first height, and
the second dielectric pillar is etched back so that the etched-back second dielectric pillar has a second height, and the second height is 20% to 75% of the first height.

13. The method according to claim 11, wherein the second dielectric pillar is formed in the active area and the dummy area, so that the second dielectric pillar and the first dielectric pillar are alternately disposed.

14. The method according to claim 11, wherein the patterning of the second dielectric pillar further comprises:
forming a photoresist layer on the second dielectric pillar in the dummy area, so that the photoresist layer covers the second dielectric pillar in the dummy area;
removing the second dielectric pillar in the active area; and
removing the photoresist layer.

15. The method according to claim 14, wherein the second dielectric pillar in the active area is removed by performing a wet etching process using the photoresist layer as an etching mask.

16. The method according to claim 14, wherein a side surface of the photoresist layer is aligned with a side surface of the first dielectric pillar in the dummy area.

17. The method according to claim 14, wherein the formation of the photoresist layer on the second dielectric pillar in the dummy area further comprises:
forming a first photoresist layer on the first dielectric pillar and the second dielectric pillar;
forming a second photoresist layer on the first photoresist layer, wherein the second photoresist layer exposes a top surface of the first photoresist layer; and
removing the first photoresist layer in the active area.

18. The method according to claim 17, wherein a viscosity of the first photoresist layer is lower than a viscosity of the second photoresist layer.

19. The method according to claim 10, wherein the formation of the first conductive layer in the active area further comprises:
depositing a material of the first conductive layer on the substrate, the first dielectric pillar, and the second dielectric pillar; and
etching back the material of the first conductive layer, wherein a top surface of the first conductive layer is lower than the top surface of the first dielectric pillar.

20. The method according to claim 19, wherein the material of the first conductive layer is etched back so that the top surface of the first conductive layer in the active area is aligned with the top surface of the second dielectric pillar in the dummy area or the top surface of the first conductive layer in the dummy area.
